(19) United States
(12) Patent Application Publication
(10) Pub. No.: US 2009/0081859 A1
(43) Pub. Date: Mar. 26, 2009

(54) Metallization process

(75) Inventors: Tuung Luoh, Taipei (TW); Ling-Wuu Yang, Hsinchu (TW); Chin-Ta Su, Yunlin (TW); Ta-Hung Yang, Miaoli (TW); Kuang-Chao Chen, Taipei (TW)

Correspondence Address: BACON & THOMAS, PLLC, 625 SLATERS LANE, FOURTH FLOOR, ALEXANDRIA, VA, 22314-1176, US

(73) Assignee: Macronix International Co., Ltd., Hsinchu (TW)

(21) Appl. No.: 11/902,228

(22) Filed: Sep. 20, 2007

(51) Int. Cl. H01L 21/425

(52) U.S. Cl. 438/530; 257/E21.473

(57) ABSTRACT

A metallization process is provided. The metallization process comprises the following steps. First, a semiconductor base having at least a silicon-containing conductive region is provided. Afterwards, nitrogen ions are implanted into the silicon-containing conductive region. Next, a first thermal process is performed on the semiconductor base for repairing the surface of the semiconductor base. Then, a metal layer is formed on the surface of the semiconductor base and the metal layer covers the silicon-containing conductive region. Lastly, a second thermal process is performed on the semiconductor base covered with the metal layer so as to form a metal silicide layer on the silicon-containing conductive region.

### BACKGROUND OF THE INVENTION

1. Field of the Invention

The invention relates in general to a metallization process, and more particularly to a metallization process capable of reducing the agglomeration of metal suicides.

2. Description of the Related Art

As the dimension of the integrated circuit (IC) element is getting smaller, the corresponding impedance of the interconnection or shallow junction also increases, making the operating speed of the IC difficult to increase. Take the polysilicon that is commonly used to form the gate and the local interconnection for example, despite the polysilicon is heavily doped, the resistance rate is still very high, resulting in undesirable power consumption and RC delay. The solution for improvement is adopting a metallization process to form a metal silicide on the conductive region of a transistor structure by self-alignment. However, when cobalt is used to react with the polysilicon gate under high temperature so as to form CoSi₂ metal silicide, the interface CoSi₂/Si is uneven and has thermal grooving, resulting in the agglomeration phenomenon, largely affecting the thermal stability of the metal silicide and the performance of the IC elements.

### SUMMARY OF THE INVENTION

The invention is directed to a metallization process, which performs a thermal process on the semiconductor base before the metal layer is deposited, such that better deposition conditions are obtained, and the agglomeration phenomenon of metal silicide that occur in subsequent thermal process is reduced.

According to the present invention, a metallization process is provided. The metallization process comprises the following steps. First, a semiconductor base having at least a silicon-containing conductive region is provided. Afterwards, nitrogen ions are implanted into the silicon-containing conductive region. Next, a first thermal process is performed on the semiconductor base for repairing the surface of the semiconductor base. Then, a metal layer is formed on the surface of the semiconductor base and the metal layer covers the silicon-containing conductive region. Lastly, a second thermal process is performed on the semiconductor base covered with the metal layer so as to form a metal silicide layer on the silicon-containing conductive region.

According to the present invention, another metallization process is provided. First, a semiconductor base having at least a silicon-containing conductive region is provided. Next, nitrogen ions are implanted into the silicon-containing conductive region. Then, a first thermal process on the semiconductor base is performed for repairing the surface of the semiconductor semiconductor base. Afterwards, a metal layer is formed on the surface of the semiconductor base. The metal layer covers the silicon-containing conductive region. Further, a diffusion barrier is formed on the metal layer. After that, a second thermal process is performed on the semiconductor base covered with the metal layer to form a metal silicide layer on the silicon-containing conductive region. The step of performing the first thermal process is further used for reducing agglomeration of the metal silicide layer.

The invention will become apparent from the following detailed description of the preferred but non-limiting embodiments. The following description is made with reference to the accompanying drawings.

### BRIEF DESCRIPTION OF THE DRAWINGS

FIG. 1 is a flowchart of a metallization process according to the invention;

FIGS. 2A˜2E are respective sectional views when the metallization process according to a preferred embodiment of the invention is applied to a transistor element.

### DETAILED DESCRIPTION OF THE INVENTION

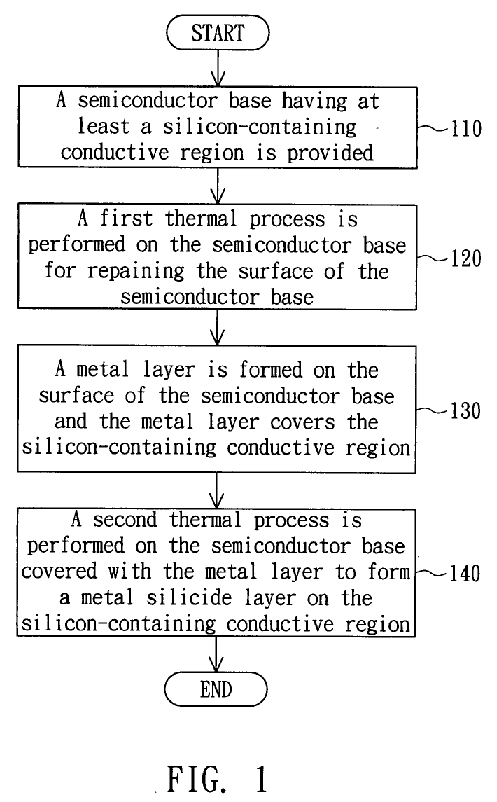

Referring to FIG. 1, a flowchart of a metallization process according to the invention is shown. Firstly, the process begins at step 110, a semiconductor base having at least a silicon-containing conductive region is provided. Next, the process proceeds to step 120, a first thermal process is performed on the semiconductor base. Then, the process proceeds to step 130, a metal layer is formed on the surface of the semiconductor base and the metal layer covers the silicon-containing conductive region. Lastly, the process proceeds to step 140, a second thermal process is performed on the semiconductor base covered with the metal layer to form a metal silicide layer on the silicon-containing conductive region.

The metallization process of the invention is exemplified by the application in an ordinary field effect transistor. However, any one who is skilled in the technology of the invention will understand that the invention can be used in any integrated circuit to improve the interconnection or the performance of IC elements, such that the overall efficiency of the integrated circuit is improved and the design of the IC manufacturing process is more flexible.

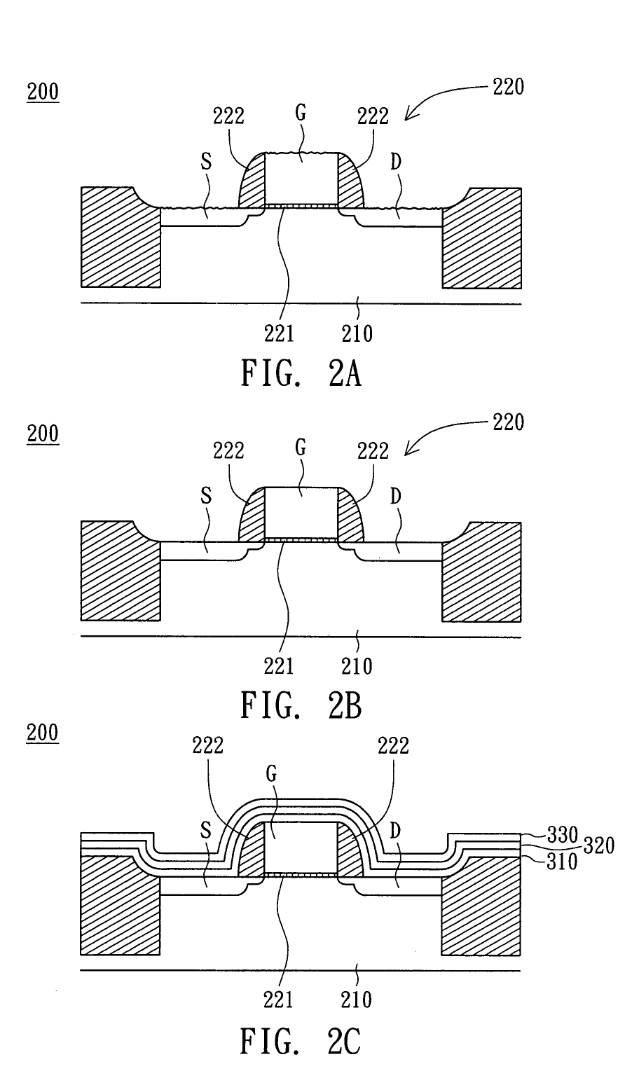

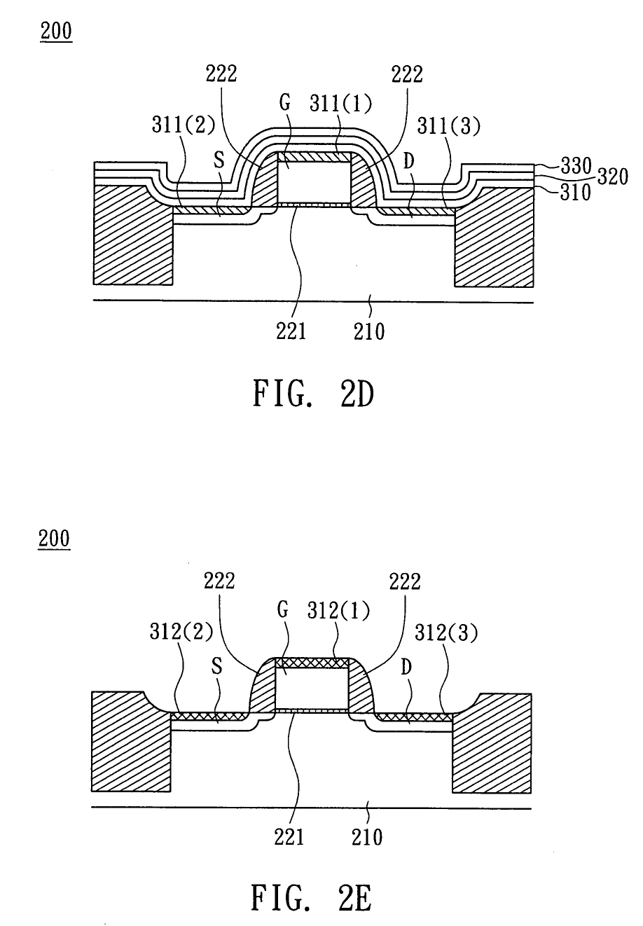

Referring to FIGS. 2A˜2E in order, respective sectional views when the metallization process according to a preferred embodiment of the invention is applied to a transistor element are shown. FIG. 2A illustrates the step 110 of providing a semiconductor base 200 having a base 210 and a transistor element 220 on the base 210. In the present embodiment of the invention, the base 210 is a P-type or N-type silicon base. However, in other embodiments, the base 210 can be a silicon-on-insulator (SOI) base. Examples of the transistor element 220 include an ordinary metal-oxide-semiconductor (MOS) transistor element having three silicon-containing conductive regions such as the gate G, the drain D and the source S. The gate G formed on the gate oxide layer 221 is a deposited and patterned polysilicon layer. The drain D and the source S are the regions doped with arsenic or boron whose polarity is opposite to the base 210, and the spacer 222 can be used as a mask for the subsequent formation of the metal silicide.

However, there are probably some inorganic or organic pollutants left on the semiconductor base 200, such as impurity particles in the manufacturing environment or residuals and by-products (polymers) generated during the photo-resist, etching or patterning process, and even the native oxides of the base 210. Besides, the surface structure of the semiconductor base 200 might be uneven due to previous process. The quality of the metallization process depends substantially on whether the surface of the silicon-containing conductive region is clean and smooth enough.

FIG. 2B illustrates the step 120 of performing a first thermal process on the semiconductor base 200. In the present embodiment of the invention, the first thermal process is exemplified by the annealing process using high-temperature furnace, such that the semiconductor base 200 is annealed within the nitrogen environment of 450 to 700□ for 20 to 180 minutes (the flow rate is approximately 1 to 10 slm, and the pressure is approximately 1 atm). In other embodiments, the first thermal process can also be a rapid thermal process (RTP) with higher temperature setting. By the first thermal process process performed, the remnants left on the semiconductor base 200 that are harmful to the subsequent metallization process are removed effectively, meanwhile the surface structure of the semiconductor base 200 is repaired, such that the silicon-containing conductive region of the transistor element 220 is more clean and smooth.

Before the metal deposition step, conventional metallization process pre-cleans the surface of the semiconductor base by hydrogen-fluoride to obtain suitable deposition conditions. However, the pre-cleaning step has limited removing effect on the above harmful remnants, and has no contribution to the improvement of the surface structure of the semiconductor base 200. Therefore, the invention achieves better deposition conditions by a thermal process as described above. The pre-cleaning step can be performed before the step 130.

FIG. 2C illustrates the step 130 of forming a metal layer 310 by sputtering deposition when achieving suitable deposition conditions in step 120. In the present embodiment of the invention, the metal layer 310 contains cobalt (Co). In other embodiments, the metal layer 310 can contain the metal such as titanium (Ti), nickel (Ni) and molybdenum (Mo). Normally, an absorbent layer 320 and a diffusion barrier 330 can be further formed on the metal layer 310 as indicated in FIG. 2C. The absorbent layer 320 can use titanium to help removing the native oxide of the base 210 so as to reduce the oxygen contamination during the subsequent formation of the metal silicide. The diffusion barrier 330 can use titanium nitride to reduce the diffusion of the the diffusion of the metal layer 310 in subsequent thermal process. Moreover, before the metal layer 310 is formed, nitrogen ions (N2+) can be implanted to the specific silicon-containing conductive regions to change the grain size of the metal silicide formed in the subsequent thermal process, and thereby reduce the agglomeration silicide.

FIG. 2D illustrated the step 140 of performing a second thermal process on the semiconductor base 200 covered with the metal layer 310, the absorbent layer 320 and the diffusion barrier 330. The second thermal process is an annealing process with 400 to 550□. Thus, the metal layer 310 containing cobalt reacts with the gate G, the drain D and the source S to form the metal silicide layer 311(1), 311(2) and 311(3) containing cobalt-silicidesilicide compound (CoSi).

Please refer to drawing attached 1 and drawing attached 2. Drawing attached 1 and drawing attached 2 are respectively electron microscopy images of a metal silicide layer forming on a semiconductor base that is kept out from and subjected to a pre-treatment process. The pre-treatment process includes the first thermal process and nitrogen ion implantation. After the semiconductor base without conducting the pre-treatment process is subjected to the second thermal process, a discontinued and irregular metal silicide layer is formed on the silicon-containing conductive region (the light color trapezoid region in drawing attached 1). The discontinuous and irregular metal silicide layer is the dark area in the top of the silicon-containing conductive region in drawing attached 1. attached 1. On the other hand, a continuous and well-shaped metal silicide layer is formed on the silicon-containing conductive region (the light color trapezoid region in drawing attached 2) after the semiconductor base undergone the pre-treatment process is subjected to the second thermal process. The continuous and well-shaped metal silicide layer is the dark area in the top of the silicon-containing conductive region in drawing attached 2. According to drawing attached 1 and drawing attached 2, the so-called agglomeration phenomenon of the metal silicide layer can be effectively reduced after pre-treating the semiconductor base by the first thermal process and nitrogen ion implantation.

Please refer to FIG. 2D. As the metal silicide layers 311(1), 311(2) and 311(3) still have high resistance, the material other than the metal silicide layers 311(1), 311(2) and 311(3) in FIG. 2D is removed by selective etching, and an annealing process with 700 to 900□ is further performed to obtain the metal silicide layer 312(1), 312(2) and 312(3) (the resistance is reduced to 3˜8 Ohm) containing CoSi₂ as indicated in FIG. 2E. Thus, the metallization process according to the invention preferred embodiment is completed. However, in other embodiments, the second thermal process in step 140 can be a rapid thermal process so as to form directly the metal silicide layer containing CoSi₂.

Thus, through achieving better deposition conditions by the first thermal process in step 120, the agglomeration of metal silicide during the subsequent one or two thermal processes can be reduced effectively, such that the metal suicide layer has higher uniformity. Therefore, there is no need to increase the deposition thickness of the metal layer in the cause of the agglomeration, meanwhile the occurrence of leak current is avoided, largely increasing the thermal stability of metal silicide, the performance of transistor elements and the product yield rate.

According to the metallization process disclosed in the above embodiments of the invention, a thermal process is performed on the semiconductor base before the metal layer is deposited such that better deposition conditions are achieved, and the agglomeration phenomenon of metal silicide that occur in subsequent thermal process is reduced. The metallization process of the invention can be applied to any integrated circuit to improve the conditions for the interconnection or element characteristics, such that the overall efficiency of integrated circuit is improved and the IC process window is more flexible.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A metallization process, comprising:
(a) providing a semiconductor base, wherein the semiconductor base has at least a silicon-containing conductive region;
(b) implanting nitrogen ions (N2⁺) into the silicon-containing conductive region;
(c) performing a first thermal process on the semiconductor base for repairing the surface of the semiconductor base;
(d) forming a metal layer on the surface of the semiconductor base, wherein the metal layer covers the silicon-containing conductive region; and
(e) performing a second thermal process on the semiconductor base covered with the metal layer to form a metal silicide layer on the silicon-containing conductive region.

2. The metallization process according to claim 1, wherein between the step (a) and the step (d), the process further comprises:
pre-cleaning the semiconductor base.

3. The metallization process according to claim 1, wherein in the step (c), the first thermal process is an annealing process or a rapid thermal process (RTP).

4. The metallization process according to claim 3, wherein in the step (c), the semiconductor base is annealed within a nitrogen environment that the temperature is approximately 450 to 700□, the flow rate is approximately 1 to 10 slm and the pressure is approximately 1 atm for about 20 to 80 minutes.

5. The metallization process according to claim 1, wherein after the step (e), the process further comprises:
(f) performing a third thermal process on the semiconductor base to form another metal silicide whose resistance value is lower than that of the metal silicide.

6. The metallization process according to claim 5, wherein the third thermal process is an annealing process with the temperature of approximately 700 to 900□.

7. The metallization process according to claim 1, wherein after the step (e), the process further comprises:
at least removing the part of the metal layer not reacting with the silicon-containing conductive region.

8. The metallization process according to claim 1, wherein between the step (d) and the step (e), the process further comprises:
forming a diffusion barrier on the metal layer.

9. The metallization process according to claim 8, wherein the diffusion barrier contains titanium nitride (TiN).

10. The metallization process according to claim 1, wherein between the step (d) and the step (e), the process further comprises:
forming an absorbent layer to absorb the native oxide on the surface of the semiconductor base.

11. The metallization process according to claim 10, wherein the absorbent layer contains titanium (Ti).

12. The metallization process according to claim 1, wherein in the step (d), the metal layer is selected from the group composed of cobalt (Co), titanium (Ti), nickel (nickel, Ni) and molybdenum (Mo).

13. The metallization process according to claim 1, wherein in the step (a),
the semiconductor base further has a silicon-on-insulator (SOI) base.

14. The metallization process according to claim 1, wherein in the step (e),
the second thermal process is an annealing process with the temperature of about 400 to 550□ or a rapid thermal process (RTP).

15. A metallization process, comprising:
(a) providing a semiconductor base, wherein the semiconductor base has at least a silicon-containing conductive region;
(b) implanting nitrogen ions into the silicon-containing conductive region.
(c) performing a first thermal process on the semiconductor base for repairing the surface of the semiconductor base;
(d) forming a metal layer on the surface of the semiconductor base, wherein the metal layer covers the silicon-containing conductive region;
(e) forming a diffusion barrier on the metal layer; and
(f) performing a second thermal process on the semiconductor base covered with the metal layer to form a metal silicide layer on the silicon-containing conductive region;
wherein the step of performing the first thermal process is further used for reducing agglomeration of the metal silicide layer.

16. The metallization process according to claim 15, wherein between the step (a) and the step (d), the process further comprises:
pre-cleaning the semiconductor base.

17. The metallization process according to claim 15, wherein in the step (c), the first thermal process is an annealing process or a rapid thermal process.

18. The metallization process according to claim 17, wherein in the step (c), the semiconductor base is annealed within a nitrogen environment that the temperature is approximately 450 to 700° C., the flow rate is approximately 1 to 10 slm and the pressure is approximately 1 atem for about 20 to 80 minutes.

19. The metallization process according to claim 15, wherein after the step (f), the process further comprises:
(g) performing a third thermal process on the semiconductor base to form another metal sillicide whose resistance value is lower than that of the metal sillicide.

20. The metallization process according to claim 19, wherein the third thermal process is an annealing process with the temperature of approximately 700 to 900□.

21. The metallization process according to claim 15, wherein after the step (f), the process further comprises:
at least removing the part of the metal layer not reacting with the silicon-containing conductive region.

22. The metallization process according to claim 15, wherein between the step (d) and the step (e), the process further comprises:
forming an absorbent layer to absorb the native oxide on the surface of the semiconductor base.

23. The metallization process according to claim 15, wherein in the step (f), the second thermal process is an annealing process with the temperature of about 400 to 550□.
